(19) United States
(12) Patent Application Publication
(10) Pub. No.: US 2005/0112403 A1
(43) Pub. Date: May 26, 2005

(54) Full color organic electroluminescent device

(76) Inventors: Sang-Hyun Ju, Seoul (KR); Mu-Hyun Kim, Seoul (KR); Jang-Hyuk Kwon, Seoul (KR); Sung-Chul Kim, Seoul (KR); Ho-Kyoon Chung, Seoul (KR); Byung-Doo Chin, Seoul (KR); Seong-Taek Lee, Seoul (KR)

Correspondence Address: CHRISTIE, PARKER & HALE, LLP, PO BOX 7068, PASADENA, CA, 91109-7068, US

(21) Appl. No.: 10/938,464

(22) Filed: Sep. 9, 2004

(30) Foreign Application Priority Data
Nov. 25, 2003 (KR) 2003-84238

(51) Int. Cl. H05B 33/12

(52) U.S. Cl. 428/690; 428/917; 313/504; 313/506; 257/89

(57) ABSTRACT

The present invention is directed to a full color organic electroluminescent device which comprises a substrate; a first electrode formed on the substrate; an organic emitting layer formed on the first electrode, and having a red-emitting layer, a green-emitting layer and a blue-emitting layer, respectively patterned in a red pixel region, a green pixel region and a blue pixel region, and having the red and green-emitting layer consisting of a phosphorescent material and the blue-emitting layer consisting of a fluorescent material; a hole blocking layer formed on the organic emitting layer as a common layer; and a second electrode formed on the hole blocking layer, so that the full color organic electroluminescent device having enhanced lifetime and luminous efficiency characteristics can be provided.

### CROSS-REFERENCE TO RELATED APPLICATION

This application claims priority to and the benefit of Korea Patent Application No. 2003-84238, filed on Nov. 25, 2003, the disclosure of which is hereby incorporated by reference in its entirety.

### BACKGROUND OF THE INVENTION

1. Field of the Invention

The present invention relates to a full color organic electroluminescent device (OLED) and, more particularly, to a full color OLED having improved lifespan and luminous efficiency characteristics.

2. Description of the Related Art

In general, an OLED consists of several layers including a positive electrode, a negative electrode, a hole injecting layer, a hole transporting layer, an organic emitting layer, an electron transporting layer, and an electron injecting layer. OLEDs are generally classified into two types based on the materials used: polymer OLEDs and small molecule OLEDs. For the small molecule type of OLED, each layer can be fabricated by a vacuum deposition process. For the polymer type of OLED, each layer can be fabricated using a spin coating process.

Multiple organic layers such as the hole injecting layer, hole transporting layer, the organic emitting layer, the hole blocking layer, and the electron injecting layer are stacked by a deposition process in accordance with the function of each layer, and then a cathode electrode is deposited thereon, thereby fabricating the small molecular OLED.

In fabricating a small molecule full color OLED using a conventional process, the hole injecting layer and the hole transporting are deposited as a common layer, and red, green and blue layers are each then deposited and patterned thereon by means of a shadow mask, and the hole blocking layer and the electron injecting layer are then deposited thereon as a common layer. Finally, the cathode electrode is deposited thereon.

For a small molecular OLED, a fluorescent or phosphorescent element can be made by introducing each layer using vacuum deposition techniques. However, because each layer is deposited using a mask, mass production is difficult. See U.S. Pat. Nos. 6,310,360, 6,303,238, and 6,097,147 for further information.

During the fabrication of a full color polymer type OLED, the red, green, and blue polymers are patterned sequentially. This can lead to problems such as low luminous efficiency and decreased lifespan when an inkjet technique or a laser induced thermal imaging process is used.

To apply the laser induced thermal imaging (LITI) process, a light source, a transfer film and a substrate are required. Light emitted from the light source is absorbed by a light absorbing layer of the transfer film and is converted into thermal energy. A transfer layer forming material of the transfer film is transferred to the substrate by the thermal energy to form a desired image as disclosed in U.S. Pat. Nos. 5,220,348, 5,256,506, 5,278,023, and 5,308,737.

The laser induced thermal imaging process may also be used to form patterns of an emitting materials as disclosed in U.S. Pat. No. 5,998,085.

U.S. Pat. No. 5,937,272 discloses a method for forming a high definition patterned organic layer in a full color OLED in which a donor support is coated with a transferable coating of an organic emitting material. The donor support is heated to cause the transfer of the organic electroluminescent material onto the designated recessed surface portions of the substrate forming the colored EL medium in the designated subpixels. In this case, the transfer to the pixel is accomplished by applying heat or light to the donor film and making the organic emitting material vaporize.

Thus, a process limitation in the fabrication of full color OLED is that fine patterning must be performed for each of the red, green and blue layers.

FIG. 1 shows a cross-sectional view of a structure of a full color OLED in accordance with a prior art.

Referring to FIG. 1, an anode electrode 12 is first deposited and patterned on the substrate 10. The anode electrode 12 defines red, green and blue pixel regions which are further defined by an insulating layer 14. An organic layer is applied to the anode electrode and insulating layer to form a hole injecting layer 16. Optionally, a hole transporting layer 18 is applied over the hole injecting layer over the entire surface of the substrate by using a vacuum deposition process of the like. Alternatively, the hole transporting layer and hole injecting layer can be applied as a common layer. Red (R) layer 100, green (G) layer 200 and blue (B) layer 300 are formed on the deposited hole injecting layer 16 and/or hole transporting layer 18 by using vacuum deposition, spin coating or laser induced thermal imaging processes. When the vacuum deposition method is used, the R, G and B layers are patterned by using a shadow mask, but when the laser induced thermal imaging process is used, a shadow mask need not be used.

A hole blocking layer 20 is then applied over the entire surface of the substrate including the R, G and B layers and an electron transport layer 22 is coated over the hole blocking layer. Alternatively, the hole blocking layer and electron transport layer can be applied as a common layer. A cathode electrode 24 is finally deposited thereon as an upper electrode.

In the prior art, when the R 100, G 200 and B 300 layers are formed in the pixel region, at least three deposition process steps or transfer process steps are required making the process becomes complicated.

In addition, when a fluorescent material is used for forming the R, G, and B layers in the pixel region as an emitting host and a phosphorescent material is used as a dopant, the hole moves faster than the electron so that the hole blocking layer is necessarily required on the emitting layer to inhibit movement of the hole.

When a fluorescent material is used as the emitting layers for the R, G, and B pixel regions, the hole blocking layer is not required, however, the luminous efficiency is low.

### SUMMARY OF THE INVENTION

It is, therefore, an object of the present invention to provide a full color OLED having an improved lifespan and luminous efficiency characteristics without requiring a new layer or an additional process step in manufacturing.

To achieve the above purpose, the present invention provides a full color OLED, which comprises a substrate; a first electrode formed on the substrate; an organic emitting layer formed on the first electrode, and having a red emitting layer, a green emitting layer and a blue emitting layer, respectively patterned in a red pixel region, a green pixel region and a blue pixel region, and having the red and green emitting layers consisting of phosphorescent materials and the blue emitting layer consisting of a fluorescent material; a hole blocking layer formed on the organic emitting layer as a common layer; and a second electrode formed on the hole blocking layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 shows a cross-sectional view of a structure of a conventional full color OLED; and

FIG. 2 shows a cross-sectional view of a structure of a full color OLED in accordance with a first example of the present invention.

FIG. 3 shows a cross-sectional view of a structure of a conventional full color OLED.

### DETAILED DESCRIPTION

The present invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

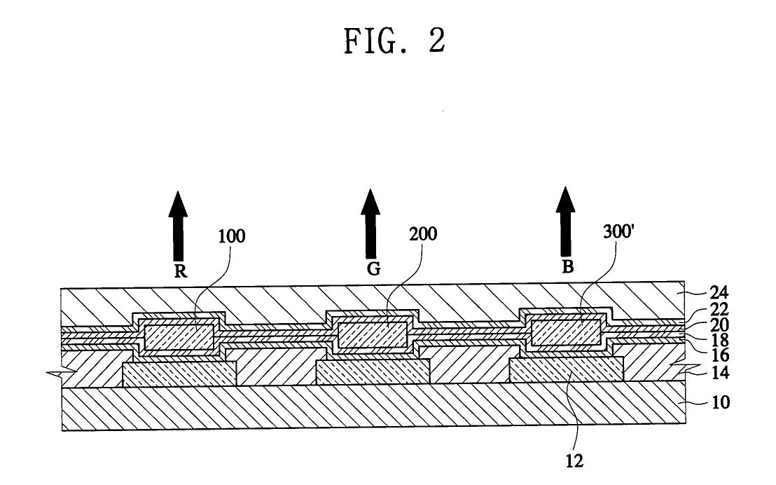

FIG. 2 shows a cross-sectional view of a full color OLED in accordance with first example of the present invention.

Referring to FIG. 2, a lower electrode 12 is first deposited and patterned on a lower substrate 10. The lower substrate uses a metal layer as a reflecting layer for a front type light emitting structure, and uses ITO or IZO as a transparent electrode for a rear type light emitting structure. An insulating layer 14 (PDL) for defining a pixel region is then formed thereon. After forming the insulating layer, an organic layer is deposited to form a hole injecting layer 16 and/or a hole transporting layer 18 over an entire surface of the substrate.

Typically, a small molecular material such as CuPc, TNATA, TCTA, TDAPB or a polymer such as PANI, PEDOT is used for the hole injecting layer. An arylamine-based monomer, a hydrazone-based monomer, a stilbene-based monomer, a starbust-based monomer such as NPB, TPD, s-TAD, MTADATA, or a carbazole-based polymer, arylamine-based polymer, peryllene-based polymer or pyrrole-based polymer such as PVK are used for the hole transporting layer.

After forming the hole injecting layer 16 and/or hole transporting layer 18, the R 100 and G 200 layers are formed over the corresponding pixel regions by patterning red and green phosphorescent materials. Then, a blue fluorescent material is applied over the blue pixel region to form a blue-emitting layer B 300′.

For the red phosphorescent material, CBP can be used as the host doped with 7 to 15% of PtOEP, R7(fabricated by UDC) or Ir(piq)3(Tris[1-phenylisoquinolinato-C2, N]iridium(III), fabricated by COVION) as the dopant.

For the green phosphorescent material, CBP can be used as the host doped with 5 to 10% of IrPPY as the dopant.

In addition, any one of small molecular materials selected from the group consisting of DPVBi, spiro-DPVBi, spiro-6P, distylbenzene (DSB), and distylaryllene (DSA) is used for the blue fluorescent material, or a PFO-based or PPV-based polymer material can be used.

The R, G and B layers are finely patterned using a shadow mask when the vacuum deposition process is used, but do not have to be patterned by means of the shadow mask when either the spin coating process or laser induced thermal imaging process is used.

The thicknesses of the red-emitting layer 100, the green-emitting layer 200 and the blue-emitting layer 300′ may be adjusted to optimize the luminous efficiency and driving voltage. A preferred thickness range is about 5 nm to 50 nm, but the thickness is not limited to this range.

After forming the R, G and B layers, the hole blocking layer 20 is formed as a common layer on the emitting layers over the entire surface of the substrate.

Typically a phosphorescent element, for example, the green phosphorescent emitting layer 200, has a Highest Occupied Molecular Orbital (HOMO) value higher than that of the electron transporting layer 22. Therefore, the hole tends to move to the electron transporting layer 22 to combine with the electron in the emitting layer to create an exciton. Such tendency causes color purity to become deteriorated.

Thus, when the fluorescent material is used for the emitting layer in the fluorescent element, the electron transporting layer 22 may be introduced immediately after the emitting layer is formed. However, for the green phosphorescent element, a hole blocking layer 20 having a HOMO value higher than that of the emitting layer 200 is required.

In the present invention, an organic material having a HOMO value of 5.5 to 6.9 eV capable of preventing exciton diffusion in the emitting layer can be used as the hole blocking layer 20. The organic material preferably has a HOMO value of 5.7 to 6.7 eV. The lifetime and diffusion distance (about 10 nm) of the exciton are longer for the phosphorescent material, so that the specified HOMO value is necessary for effectively blocking the hole injected into the emitting layer.

The organic material may be one selected from the group consisting of 2,9-dimethyl-4,7-diphenyl-1,10-phenanthroline, Aluminum(III)bis(2-methyl-8-quinolinato)-4-phenylphenolate, i.e. BAlq, CF-X:C60F42 and CF-Y:C60F42.

While phosphorescent materials are used for the red and green pixels, a blue fluorescent material is used for the blue-emitting material, so that the thickness of the hole blocking layer can be optimized in the present invention. This is because the thicker the hole blocking layer, the better the luminous efficiency for the phosphorescent layer if possible. However, luminance and color purity of the pure blue color are affected by the hole blocking layer for the blue fluorescent layer.

If the thickness of the hole blocking layer 20 is 20 Å or less, the luminous efficiency of the phosphorescent layer is very low, and the luminance of the phosphorescent layer becomes drastically lower if the thickness is 150 Å or more, so that it is preferable to have a thickness of 20 to 150 Å, and more preferable to have a thickness of 40 to 150 Å that optimizes the luminous efficiency of the phosphorescent layer.

The electron transporting layer and/or the electron injecting layer are then formed by means of known methods, and an upper electrode 24 is deposited and encapsulated over the entire surface of the substrate thereon, thereby fabricating the full color OLED.

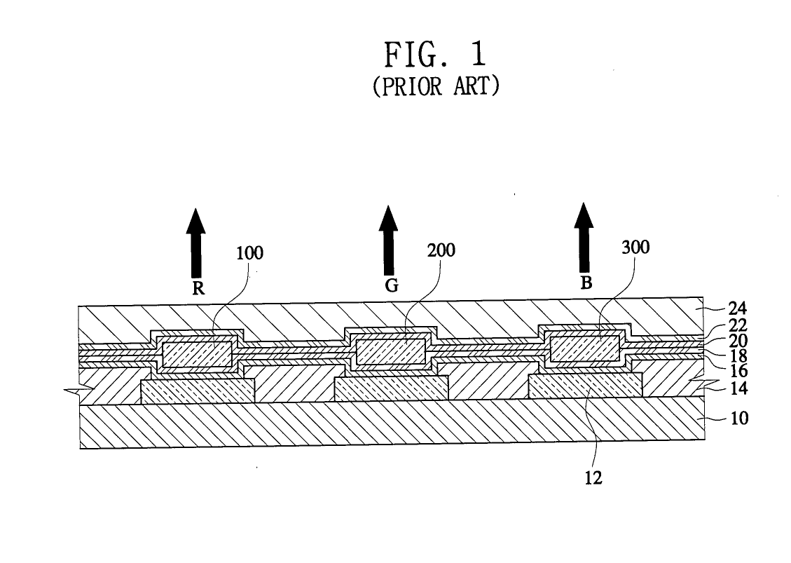

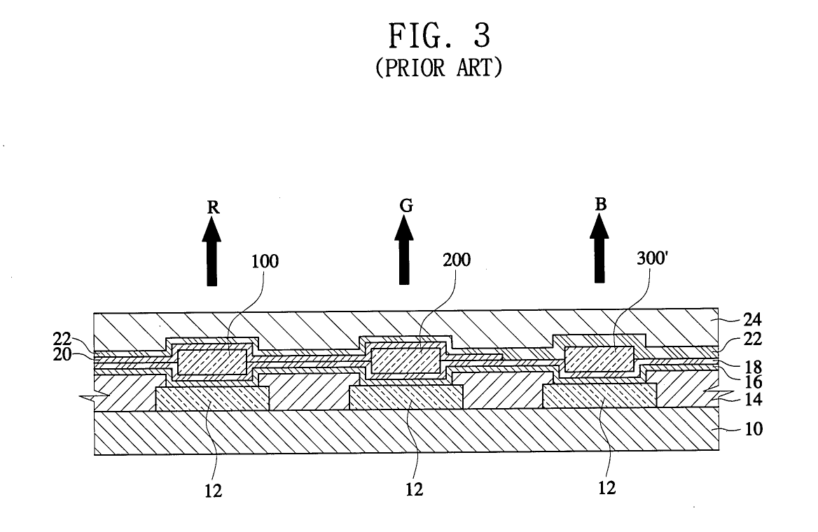

FIG. 3 shows a cross-sectional view of another conventional full color OLED in which a fluorescent material 300′ is used as the emitting layer for the blue pixel region while phosphorescent materials 100, 200 are used as the emitting layers for the red and green pixel regions. The construction of the substrate 10, anode electrode 12, insulating layer 14, hole injecting layer 16 and hole transporting layer 18 are similar to the device of FIG. 1. however, while the hole transporting layer applied over the red and green phosphorescent materials for this device, in order to provide improved luminous efficiency for the blue layer, the hole blocking layer does not extend over the blue layer. The electron transport layer 22 and cathode electrode 24 are as set forth in other OLEDs. While such a construction exhibits good luminous efficiency, its manufacture is more complicated than for a device with a continuous hole blocking layer.

As mentioned above, by forming the hole blocking layer as a common layer over the entire surface of the emitting layer, the full color OLED can be made by a reduced number of process steps compared to a process in which the hole blocking layer is formed only on the phosphorescent layer while achieving almost equivalent levels of lifespan and luminous efficiency as shown in FIG. 3.

Hereinafter, preferred experimental examples of the present invention will be described. However, the experimental examples below are described to better understand the present invention and not limited to these embodiments.

### EXAMPLES 1-3

Fabrication of the Blue Fluorescent Device

Ultrasonic cleaning is performed on an ITO substrate (i.e., first electrode) patterned to a width of 80 μm and a UV/O₃ process is then performed for 15 minutes. A small molecular hole injecting layer (IDE 406; fabricated by IDEMITZ with a HOMO value of 5.1 eV) is then vacuum deposited at a pressure of 8×10⁻⁷ mbar Pa to a thickness of 600 Å. A small molecular hole transporting layer (IDE 320; fabricated by IDEMITZ with a HOMO value of 5.4 eV) is deposited at the same pressure to a thickness of 300 Å. For the emitting layer of the blue fluorescent device, IDE 140 (fabricated by IDEMITZ corporation with a HOMO value of 5.7 eV and a LUMO value of 2.7 eV) as a host and IDE 105 (fabricated by IDEMITZ and has a HOMO value of 5.4 eV and a LUMO value of 2.6 eV) as a dopant at a concentration of 7% by weight are vacuum deposited to a thickness of 200 Å.

For the hole blocking layer, Aluminum(III)bis(2-methyl-8-quinolinato)-4-phenylphenolate (Balq; fabricated by UDC) is deposited to thicknesses of 50 Å, 100 Å and 150 Å, respectively for Examples 1-3, and the electron transporting layer Alq3 is then deposited to a thickness of 200 Å on the emitting layer, and the electron injecting layer of LiF is deposited to a thickness of 20 Å and an Al cathode electrode is deposited thereon to a thickness of 3000 Å, thereby fabricating a test cell.

### EXAMPLES 4 AND 5

Test cells are fabricated by the same method as Examples 1-3, except that HBM010 (PL max: 398/422 nm; fabricated by COVION) is deposited to thicknesses of 50 Å and 100 Å, respectively for Examples 4 and 5 for the hole blocking layers instead of Balq.

### EXAMPLES 6-9

Fabrication of the Red Phosphorescent Device

Ultrasonic cleaning is performed on an ITO substrate (i.e., first electrode) patterned to a width of 80 μm and a UV/O₃ process is then performed for 15 minutes. A small molecular hole injecting layer (IDE 406; fabricated by IDEMITZ with a HOMO value of 5.1 eV) is then formed to a thickness of 600 Å by vacuum deposition at a pressure of 8×10⁻⁷ mbar Pa. A small molecular hole transporting layer (IDE 320; fabricated by IDEMITZ with a HOMO value of 5.4 eV) is deposited at the same pressure to a thickness of 300 Å. For the emitting layer of the red phosphorescent device, 4,4′-N,N′-dicarbazole biphenyl(CBP; fabricated by UDC) as a host and PtOEP (fabricated by UDC) as a dopant at a concentration of 10% by weight are vacuum deposited to a thickness of 300 Å.

For the hole blocking layer, Aluminum(III)bis(2-methyl-8-quinolinato)-4-phenylphenolate (Balq; fabricated by UDC) is deposited to thicknesses of 20 Å, 50 Å and 100 Å, respectively for Examples 6-8, and the electron transporting layer Alq3 is then deposited to a thickness of 200 Å on the emitting layer. An electron injecting layer of LiF is deposited to a thickness of 20 Å and an Al cathode electrode with a thickness of 3000 Å is deposited thereon, thereby fabricating a test cell.

### COMPARATIVE EXAMPLE 1

A test cell having the same structure as that in the Example 6 was fabricated except that the hole blocking layer was not formed on the red phosphorescent element.

### EXAMPLES 10-13

Fabrication of the Green Phosphorescent Device

Ultrasonic cleaning is performed on an ITO substrate (i.e., first electrode) patterned to a width of 80 μm and a UV/O₃ process is then performed for 15 minutes. The small molecular hole injecting layer (IDE 406; fabricated by IDEMITZ with a HOMO value of 5.1 eV) is then formed to a thickness of 600 Å by vacuum deposited at a pressure of 8×10⁻⁷ mbar Pa. A small molecular hole transporting layer (IDE 320; fabricated by IDEMITZ with a HOMO value of 5.4 eV) is deposited at the same pressure to a thickness of 300 Å. For the emitting layer of the green phosphorescent element, 4,4′-N,N′-dicarbazole biphenyl (CBP; fabricated by UDC) as a host with Ir(ppy)3 (fabricated by UDC) as a dopant at a concentration of 7% by weight are vacuum deposited to a thickness of 250 Å.

For the hole blocking layer, Aluminum(III)bis(2-methyl-8-quinolinato)-4-phenylphenolate; BAlq (fabricated by UDC) is deposited to thicknesses of 20 Å, 50 Å, 100 Å and 150 Å, respectively for Examples 10-13, and the electron transporting layer Alq3 is then deposited to a thickness of 200 Å on the emitting layer, and the electron injecting layer. An electron injecting layer of LiF is deposited to a thickness of 20 Å and an Al cathode electrode with a thickness of 3000 Å is deposited thereon, thereby fabricating a test cell.

### COMPARATIVE EXAMPLE 2

A test cell having the same structure as that of Example 10 was fabricated except that the hole blocking layer was not formed on the green phosphorescent element.

Table 1 shows the result of element characteristics such as luminance, efficiency, and the like measured at 5V for the test cells fabricated according to the examples to determine the effects the variations in thickness of the hole blocking layer have on the characteristic of the OLED.

TABLE 1

| Thickness | | Luminous | | |
|---|---|---|---|---|
| of the Hole | Luminance (cd/ | efficiency | | |
| blocking layer (Å) | m², 5 V) | (cd/A, 5 V) | CIE x | CIE y |
| Example 1 (50) | 1013.0 | 5.88 | 0.145 | 0.149 |
| Example 2 (100) | 724.2 | 5.97 | 0.146 | 0.180 |
| Example 3 (150) | 460.2 | 6.03 | 0.160 | 0.210 |
| Example 6 (20) | 250.5 | 4.31 | 0.679 | 0.319 |
| Example 7 (50) | 426.3 | 5.20 | 0.680 | 0.318 |
| Example 8 (100) | 610.4 | 5.44 | 0.677 | 0.318 |
| Example 9 (150) | 339.6 | 5.77 | 0.681 | 0.317 |
| Example 10 (20) | 222.0 | 17.66 | 0.291 | 0.576 |
| Example 11 (50) | 266.7 | 22.41 | 0.299 | 0.600 |
| Example 12 (100) | 321.0 | 24.54 | 0.292 | 0.610 |
| Example 13 (150) | 213.1 | 25.14 | 0.282 | 0.626 |
| Comparative | 116.5 | 1.31 | 0.680 | 0.316 |
| Example 1 (0) | | | | |
| Comparative | 40.6 | 2.55 | 0.308 | 0.557 |
| Example 2 (0) | | | | |

As can be seen from Table 1, when the phosphorescent material is used for the emitting layer in Examples 6 to 9 (which use the red phosphorescent material) and Examples 10 to 13 (which use the green phosphorescent material), luminance and luminous efficiency are improved when the hole blocking layer is deposited with a thickness of 50 Å and 100 Å compared to 20 Å.

While the difference in luminous efficiency between the 150 Å and 100 Å thickness of the hole blocking layer is not large, the corresponding difference in luminance shows a significant reduction of about 30% or more. In addition, it can be seen from Comparative Example 1 (which uses the red phosphorescent material) and Comparative Example 2 (which uses the green phosphorescent material), which do not use the hole blocking layer at all, there is a significant reduction in the luminance and luminous efficiency compared to the 20 Å thickness of the hole blocking layer.

For color coordinates, there is no great difference in terms of color purity whether or not the hole blocking layer is used.

For the blue-emitting layer using fluorescent material as the emitting layer, as can be seen from Examples 1 to 3, the luminance is much better and the luminous efficiency is worse where the hole blocking layer is not stacked, compared to the where the hole blocking layer is stacked. In contrast, where the thick hole blocking layer is stacked (for example, 150 Å of the third experimental example), the luminance is worse than where there is no hole blocking layer and the luminous efficiency is better than the first experimental example.

Where there is no hole blocking layer or where there is a 150 Å thick hole blocking layer, both cases show sufficient luminance and luminous efficiency characteristics are obtained for the full color OLED. In other words, the luminance using the blue fluorescent layer with the 150 Å thick hole blocking layer stacked (Example 3), i.e., 460.2 cd/m² is almost equivalent to or better than that using the red or green phosphorescent layer (Examples 6 to 9 and 10 to 13). Furthermore, in terms of luminous efficiency, it can be seen that the efficiency for a blue fluorescent layer without the hole blocking layer (Example 1) is worse than for the green phosphorescent layer (Examples 10 to 13), but is not significantly different than that of the red phosphorescent layer (Examples 6 to 9).

As mentioned above, a full color OLED according to the present invention uses an emitting layer consisting of a phosphorescent layer and a fluorescent layer together with a hole blocking layer suitable for properties of each emitting layer, so that manufacturing cost can be reduced in accordance with the reduced number of masks in the fabrication process when the hole blocking layer is used as the common layer. A full color OLED having enhanced luminance, luminous efficiency, color purity, and the like can also be provided.

While the present invention has been described with reference to particular embodiments, it is understood that the disclosure has been made for purpose of illustrating the invention by way of examples and is not intended to limit the scope of the invention. One skilled in the art can change the examples without departing from the scope and spirit of the invention.

1. A full color organic electroluminescent device, comprising:
a substrate;
a first electrode formed on the substrate;
an organic emitting layer formed on the first electrode, and having a red-emitting layer, a green-emitting layer and a blue-emitting layer, respectively patterned in a red pixel region, a green pixel region and a blue pixel region, wherein each of the red and green-emitting layers comprises a phosphorescent material and the blue-emitting layer comprises a fluorescent material;
a hole blocking layer formed on the organic emitting layer as a common layer; and
a second electrode formed on the hole blocking layer.

2. The full color organic electroluminescent device as claimed in claim 1, wherein the hole blocking layer is an organic material having a HOMO value of 5.5 to 6.9 eV.

3. The full color organic electroluminescent device as claimed in claim 2, wherein the hole blocking layer is an organic material having a HOMO value of 5.7 to 6.7 eV.

4. The full color organic electroluminescent device as claimed in claim 2, wherein the organic material is selected from the group consisting of 2,9-dimethyl-4,7-diphenyl-1,10-phenanthroline, Aluminum(III)bis(2-methyl-8-quinolinato)-4-phenylphenolate (Balq), CF-X:C60F42 and CF-Y:C60F42.

5. The full color organic electroluminescent device as claimed in claim 1, wherein the hole blocking layer is from 20 Å to 150 Å in thickness.

6. The full color organic electroluminescent device as claimed in claim 5, wherein the hole blocking layer is from 40 Å to 150 Å in thickness.

7. The full color organic electroluminescent device as claimed in claim 1, wherein the red phosphorescent material comprises CBP as a host doped with a dopant selected from the group consisting of PtOEP, R7 and Ir(piq)3, and the green phosphorescent material comprises CBP as a host doped with Ir(ppy)3 as a dopant.

8. The full color organic electroluminescent device as claimed in claim 7, wherein the dopant concentration of the red phosphorescent material is from 7 to 15%, and the dopant concentration of the green phosphorescent material is from 5 to 10%.

9. The full color organic electroluminescent device as claimed in claim 1, wherein the blue fluorescent material is selected from the group consisting of small molecular DPVBi, spiro-DPVBi, spiro-6P, distylbenzene (DSB) and distylaryllene (DSA) and PFO-based and PPV-based polymers.

10. The full color organic electroluminescent device as claimed in claim 9, wherein the thickness of each of the red and green phosphorescent layers and the blue fluorescent layer is from 5 to 50 nm.

11. The full color organic electroluminescent device as claimed in claim 1, wherein the red and green phosphorescent materials and the blue fluorescent material are formed by a process selected from the group consisting of vacuum deposition, spin coating and laser induced thermal imaging.
